(19) United States
(12) Patent Application Publication
(10) Pub. No.: US 2003/0188686 A1
(43) Pub. Date: Oct. 9, 2003

(54) Semiconductor manufacturing apparatus and manufacturing method for semiconductor device

(75) Inventor: Tadashi Miyagi, Hyogo (JP)

Correspondence Address: McDERMOTT, WILL & EMERY, 600 13th Street, N.W., Washigton, DC, 20005-3096, US

(73) Assignee: Mitsubishi Denki Kabushiki Kaisha

(21) Appl. No.: 10/263,087

(22) Filed: Oct. 3, 2002

(30) Foreign Application Priority Data
Apr. 4, 2002 (JP) 2002-102844 (P)

(51) Int. Cl. C23C 16/00

(52) U.S. Cl. 118/715

(57) ABSTRACT

A level to detect a horizontal holding state of a wafer by a chuck is provided on a side surface portion of chuck supporting wafer. This device provides a semiconductor manufacturing apparatus allowing a uniform application of a prescribed liquid on the wafer in a manufacturing step of a semiconductor, and provides a semiconductor device thus manufactured.

### BACKGROUND OF THE INVENTION

1. Field of the Invention

The present invention relates to a semiconductor manufacturing apparatus and a manufacturing method for semiconductor device and, more specifically, to a semiconductor manufacturing apparatus used for a lithography step as one of manufacturing steps of a semiconductor, and a manufacturing method for semiconductor device manufactured by the semiconductor manufacturing apparatus.

2. Description of the Background Art

In a lithography step as one of manufacturing steps of a semiconductor, resist is applied on a wafer, and then a prescribed pattern is exposed on this resist using ultraviolet light or the like. Thereafter, the resist is developed with developer such as alkaline solution, and an integrated circuit having a prescribed pattern is patterned on the wafer. To apply the developer on the resist on the wafer, a method of forming a pool (puddle) of developer 200 utilizing surface tension as shown in FIGS. 3A and 3B is adopted. In addition, in the development step, wafer 1 is left until a chemical reaction of the resist and developer 200 is completed, and then developer 200 is washed with pure water to complete the formation of resist 200 on wafer 1.

When the method of forming a puddle of developer 200 as described above is adopted, as this method utilizes surface tension, there may be a, region on wafer 1 not uniformly covered with developer 200, as a region indicated by Y2 in FIG. 4, if a unit for mounting wafer 1 (a semiconductor manufacturing apparatus) is inclined upon a formation of the puddle of developer 200.

Thus, a desired pattern will not be formed on the resist due to this region with nonuniform application of developer 200. As a result, when a semiconductor is patterned using this defective resist, an irregular line width or other pattern defects may occur in the semiconductor device, and therefore, a manufacturing yield of the semiconductor device may become lower.

### SUMMARY OF THE INVENTION

The present invention was made to solve the above-mentioned problem. An object of the present invention is to provide a semiconductor manufacturing apparatus allowing uniform application of a prescribed liquid on a wafer in a manufacturing step of semiconductor, and a manufacturing method for semiconductor device manufactured using this semiconductor manufacturing apparatus.

A semiconductor manufacturing apparatus according to the present invention includes a wafer holding device for holding a wafer in a horizontal state, a liquid feeding device for feeding a prescribed liquid on a surface of the wafer, and a horizontal holding state detection device for detecting a horizontal holding state of the wafer by the wafer holding device.

According to this semiconductor manufacturing apparatus, the holding state of the wafer by the wafer holding device can continuously be monitored by the horizontal holding state detection device. As a result, it is possible to continuously maintain the holding state of the wafer by the wafer holding device in the horizontal state by, for example, feeding back the information obtained from the horizontal holding state detection device to the wafer holding device using a control device of the semiconductor manufacturing apparatus.

In the present invention, it is preferable that the wafer holding device extends in a vertical direction and has a column-shaped chuck to hold the wafer on its top end side in the horizontal state, and the horizontal holding state detection device is provided on a side surface portion of the chuck.

By keeping the chuck horizontal, the wafer can be held horizontally so as to obtain the function and effect of the present invention as described above.

In addition, the horizontal holding state detection device is preferably a digital level in the present invention. This use of the digital level enables display of an angle of the holding state of the wafer on a front surface of the semiconductor device, for example, and therefore a continuous visual monitoring becomes possible.

In the present invention, the liquid feeding device preferably includes a developer feeding device to feed developer on the surface of the wafer, and a rinsing water feeding device to feed rinsing water on the surface of the wafer.

According to the semiconductor manufacturing apparatus, because the developer can uniformly be applied on the wafer, the occurrence of the pattern defect due to nonuniform application of the developer can be avoided, and therefore the manufacturing yield of the semiconductor device can be increased.

In addition, the manufacturing method for semiconductor device according to the present invention is manufactured by using the above-mentioned semiconductor manufacturing apparatus. Therefore, the manufacturing yield of the semiconductor device can be increased, and the manufacturing cost of the semiconductor device can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a schematic arrangement of a development unit 100 in an embodiment according to the present invention.

FIG. 2 shows an effect in the embodiment in comparison with an example of the prior art.

FIGS. 3A and 3B show an example of a puddle of a developer 200, uniformly formed over an entire surface of a wafer. FIG. 3A is a partial enlarged view of a region indicated by Y1 in FIG. 3B. FIG. 3B is a side view schematically showing a wafer 1 on which developer 200 is applied.

FIGS. 4A and 4B show an example of a puddle of developer 200 not uniformly formed over an entire surface of the wafer. FIG. 4A is a partial enlarged view of a region indicated by Y2 in FIG. 4B. FIG. 4B is a side view schematically showing wafer 1 on which developer 200 is applied.

### DESCRIPTION OF THE PREFERRED EMBODIMENT

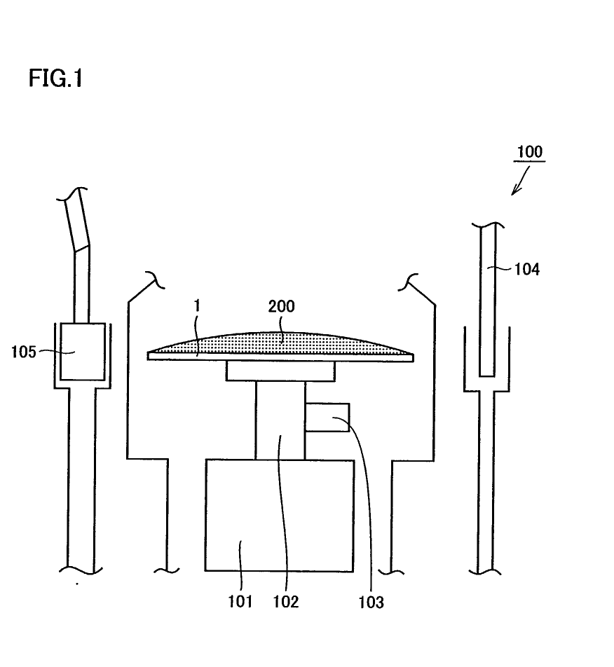

An embodiment of a semiconductor manufacturing apparatus according to the present invention will now be described with reference to the drawings. The semiconductor manufacturing apparatus of the embodiment is a development unit used for a lithography step as one of manufacturing steps of a semiconductor as described above associated with the prior art. The schematic arrangement thereof is shown in FIG. 1.

Development unit 100 includes a body 101 and a chuck 102 as a column-shaped wafer holding means provided on body 101 and extended vertically to hold wafer 1 on its top end side in a horizontal state. In addition, development unit 100 is provided with a developer nozzle 105 as a developer feeding means to feed developer 200 on the surface of wafer 1, and a pure water rinse nozzle 104 as a rinsing water feeding means to feed rinsing water (such as pure water) on the surface of wafer 1 after the development processing.

A level 103 as a horizontal holding state detection means for detecting a horizontal holding state of wafer 1 by chuck 102 is further provided on a side surface portion of chuck 102. Level 103 may be attached directly on the side surface portion of chuck 102 which directly supports wafer 1, or it may be mounted on a holder or the like previously provided on the side surface portion of chuck 102.

Though an arrangement of attaching level 103 on chuck 102 which holds wafer 1 is shown from the viewpoint of detecting the horizontal holding state of wafer 1 with high accuracy, a position for providing level 103 is not limited on chuck 102. Level 103 can be provided on any empty region of semiconductor manufacturing apparatus 100, as it is the case that the horizontal holding state of wafer 1 is maintained as long as the whole development unit 100 is kept horizontal.

In addition, while level 103 can either be in an analog or a digital format, if the digital format is adopted, it will be possible to easily indicate an angle of holding state of wafer 1 on a front surface of development unit 100, for example, to allow a continuous visual monitoring.

(Function and Effect)

According to development unit 100 in the embodiment, the holding state of wafer 100 by chuck 102 can continuously be monitored by level 103. As a result, the holding state of wafer 1 by chuck 102 can continuously be maintained in the horizontal state by, for example, feeding back information obtained from level 103 to chuck 102 using a control device of development unit 100.

Therefore, it will become possible to form a puddle of developer 200 on a resist uniformly over the entire surface of the wafer to uniformly cover the wafer surface with developer 200. With this, an occurrence of a pattern defect due to the nonuniform application of developer 200 can be avoided, and a manufacturing yield of the semiconductor device can be increased.

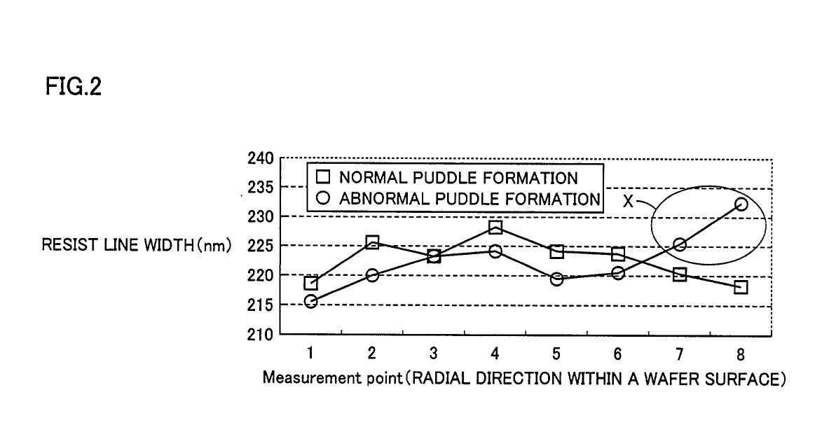

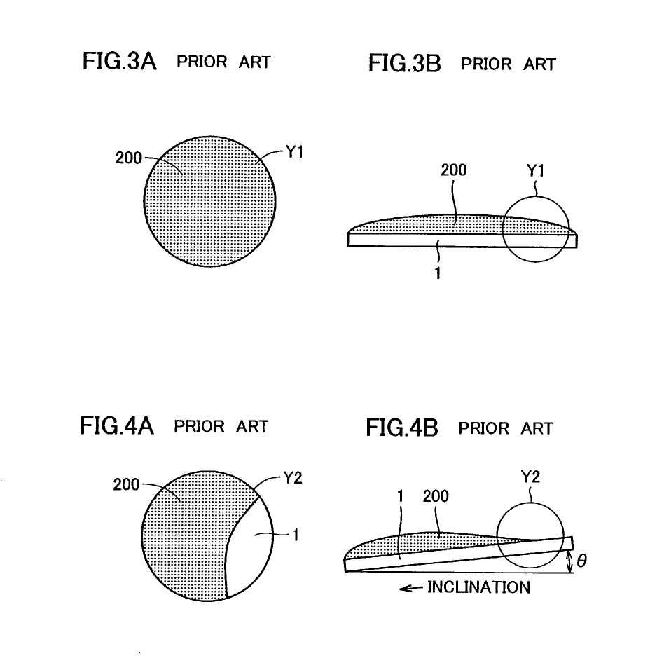

FIG. 2 shows a comparison between resist line widths after development, which result from the puddle of developer 200 uniformly formed over the entire surface of the wafer (normal puddle formation), and from the puddle not uniformly formed over the entire surface of the wafer (abnormal puddle formation).

As shown in FIG. 2, when the puddle is formed normally, the resist line width did not change even in outer circumference side along a radial direction within the wafer surface. On the other hand, when the puddle is formed abnormally, the resist line width was undesirably increased in the outer circumference side along the radial direction within the wafer surface (the region indicated by X in the drawing).

In addition, when a semiconductor device is manufactured using the semiconductor manufacturing apparatus shown in the embodiment, the manufacturing yield of the semiconductor device can be increased and the manufacturing cost of the semiconductor device can be reduced.

It is to be noted that, though the example of applying the present invention to the development unit is described in the above-mentioned embodiment, the present invention can also be applied to the other units having structures to form a pool of prescribed liquid on wafer 1, such as an application unit and a wafer rinsing unit.

According to the semiconductor manufacturing apparatus and the manufacturing method for semiconductor device based on the present invention, the holding state of the wafer by the wafer holding device can continuously be monitored by the horizontal holding state detection device. As a result, it is possible to continuously maintain the wafer holding state of the wafer by the wafer holding device in the horizontal state by, for example, feeding back the information obtained from the horizontal holding state detection device to the wafer holding device using a control device of the semiconductor manufacturing apparatus.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor manufacturing apparatus, comprising:
wafer holding means for holding a wafer in a horizontal state;
liquid feeding means for feeding a prescribed liquid on a surface of said wafer; and
horizontal holding state detection means for detecting a horizontal holding state of the wafer by said wafer holding means.

2. The semiconductor manufacturing apparatus according to claim 1, wherein:
said wafer holding means extends in a vertical direction and has a column-shaped chuck to hold said wafer on its top end side in a horizontal state, and
said horizontal holding state detection means is provided on a side surface portion of said chuck.

3. The semiconductor manufacturing apparatus according to claim 1, wherein:
said horizontal holding state detection means is a digital level.

4. The semiconductor manufacturing apparatus according to claim 1, wherein:
said liquid feeding means includes
developer feeding means for feeding developer on the surface of said wafer, and
rinsing water feeding means for feeding rinsing water on the surface of said wafer.

5. A manufacturing method for semiconductor device manufactured by using a semiconductor manufacturing apparatus including
wafer holding steps for holding a wafer in a horizontal state,
liquid feeding steps for feeding a prescribed liquid on a surface of said wafer, and
horizontal holding state detection steps for detecting a horizontal holding state of the wafer by said wafer holding means.
